(19) United States
(12) Patent Application Publication
(10) Pub. No.: US 2018/0155184 A1
(43) Pub. Date: Jun. 7, 2018

(54) BONDLINE FOR MM-WAVE APPLICATIONS

(71) Applicant: Innovative Micro Technology, Goleta, CA (US)

(72) Inventors: Christopher S. GUDEMAN, Lompoc, CA (US); Marin SIGURDSON, Goleta, CA (US)

(73) Assignee: Innovative Micro Technology, Goleta, CA (US)

(21) Appl. No.: 15/832,276

(22) Filed: Dec. 5, 2017

Related U.S. Application Data
(60) Provisional application No. 62/430,394, filed on Dec. 6, 2016.

(51) Int. Cl. B81B 3/00; H01L 23/48; H01L 23/66

(52) U.S. Cl. CPC B81B 3/0024; B81B 3/0086; H01L 23/481; B81B 2201/014; B81B 2203/0118; B81B 2207/07; B81B 2207/094; H01L 23/66

(57) ABSTRACT

We describe here a method that employs through substrate vias (TSVs) to frustrate the standing waves that are formed in the metal trace. TSVs may be formed at intervals in the first substrate, electrically coupling the metal bondline to the ground plane.

### CROSS REFERENCE TO RELATED APPLICATIONS

This US nonprovisional Patent Application claims priority to U.S. Provisional Application Ser. No. 62/430394, filed Dec. 6, 2016 and incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a system for bonding wafers to make devices for mm-wave applications.

The very small size of a microelectromechanical systems (MEMS) relay is attractive for RF applications because it generally employs metal features and dielectric thicknesses that are small compared to the wavelength of the RF signals that are transmitted through the switch structure. Recent demand for bandwidth for communication channels and radar for autonomous vehicles has pushed the operating frequencies beyond 10 GHz, where the wavelength of radiation once again becomes comparable to metal traces used in MEMS switches and relays. One particularly long metal trace is the metal bondline, which provides a required hermetic seal. Standing waves can form in these metal traces, resulting in large regions of the spectrum where the throughput, or insertion loss, is adversely impacted. These regions of the spectrum are often referred to as drop-outs or suck-outs. Thus a method is needed to frustrate or impede these standing waves.

MEMS switches are known that use a glass frit bondline. Because this adhesive is not metallic, it cannot support a standing wave and thus no drop outs are created in the bondline. However the glass frit material contains lead, a metal that tightly regulated. Furthermore, the RF signal to and from the encapsulated switch must be transmitted through lateral traces, which (1) couple strongly to the substrate and are therefore lossy, (2) increase the length of the transmission path (thereby increasing inductance and adding to losses), and (3) require large areas of the fabrication substrate and are thus expensive.

Accordingly, what is needed is a bonding technology that does not interfere with the reception or transmission of the radio frequency (RF) signals being handled by the device.

### SUMMARY

We describe here a method that employs through substrate vias (TSVs) to frustrate the standing waves that are formed in the metal trace. In one embodiment, a metal bondline may form a complete ring, hermetically enclosing the MEMS device. In this structure there may be a ground plane on one surface. The bond seal may be made when two wafers are bonded together using a malleable metal, such as Au, on each wafer. These two layers can be compressed together to form a thermo-compression bond or they can be soldered together by depositing a metal, for instance In or Sn, that readily alloys with the bondline then following with a thermal cycle to create the alloy. This metal bondline may be grounded at intervals as described herein, so that it is no longer electrically floating. The grounding may be accomplished by electrically connecting the bondline to the device ground, for example. As a result, the bondline may no longer act as a receiver or antenna for RF radiation at the characteristic frequency of the RF signal, and thus interfere with the functioning of the MEMS device.

TSVs may be formed at intervals in the first substrate, electrically coupling the metal bondline to the ground plane, and thus to the device ground. The first substrate may then be bonded to a second substrate with a metallic adhesive bonding material. The interval between the vias may be chosen to match the radiation being switched, such that the radiation modes cannot be supported by the bondline. As a result, the bondline may not interfere with the handling of the signals at their characteristic frequency.

More generally, a microfabricated structure is disclosed which supports signals having a characteristic wavelength of λ. The structure may include a metallic wafer bonding material that bonds a first wafer to a second wafer, a ground plane which may be held at ground potential relative to the wafer bonding material, and a plurality of through wafer vias extending through at least one of the first substrate and the second substrate, that defines a conductive path between the ground plane and the metallic bonding material. The through wafer vias may be disposed at intervals of between about 2λ and λ/10. A method for fabricating this structure is also disclosed, and may include forming a plurality of through wafer vias extending through at least one of a first substrate and a second substrate, that define a conductive path between a ground plane and a metallic bonding material, wherein the through wafer vias are disposed at intervals of between about 2λ and λ/10, forming the ground plane which is held at ground potential relative to the wafer bonding material, and applying the metallic wafer bonding material to the first wafer or the second wafer.

Because the bondline can no longer support the modes of the signal, the bondline no longer interferes, by absorption and/or re-radiation, of the RF signal.

### BRIEF DESCRIPTION OF THE DRAWINGS

Various exemplary details are described with reference to the following figures, wherein:

FIG. 1 is a perspective drawing of an exemplary architecture for a novel bondline for a mm-wave device;

FIG. 2 is a plan view of the exemplary architecture for a novel bondline for a mm-wave device;

FIG. 3 is a cross sectional diagram of an exemplary architecture for a novel bondline for a mm-wave device;

FIG. 4 is a cross sectional diagram of an exemplary architecture for a dual substrate switch using the novel bondline structure; and

FIG. 5 is a data plot showing the suppression of certain frequencies in the transmission characteristics of an RF device in a cavity.

It should be understood that the drawings are not necessarily to scale, and that like numbers may refer to like features.

### DETAILED DESCRIPTION

Using the prior approach of simply forming a bondline between two substrates will create a bond seal that is electrically floating. Unfortunately in this case the bondline will likely form a standing wave if the total bond length is an integer multiple of the wavelength of the radiation. Acting as an antenna, the bondline can interfere with the radiation that is being handled by the device, by absorption and re-radiation of the signal, causing loss and distortion.

We describe here a method that employs through substrate vias (TSVs) to frustrate the standing waves that are formed in the metal trace or bondline. The specific case described here relates to the metal bondline that forms a complete ring, hermetically enclosing a MEMS device. In this structure, there may be a ground plane on one surface, which is a very low resistivity film such as Au or Al and is grounded to external circuitry in several places. This film is typically 0.5-3.0 um in thickness. The bond seal is made when two wafers are bonded together using a malleable metal, such as Au, on each wafer. The thickness is typically 0.5-3.0 um. These two layers can be compressed together to form a thermo-compression bond or they can be soldered together by depositing a metal, for instance In or Sn, that readily alloys with the bondline then following with a thermal cycle to create the alloy.

TSVs may be formed at intervals in the first substrate, electrically coupling the metal bondline to the ground plane. The first substrate is then bonded to a second substrate with a metallic adhesive bonding material. The interval between the vias may be chosen depending on the radiation being switched, such that the radiation modes cannot be supported by the bondline. As a result, the bondline may not interfere with the handling of the signals at their characteristic frequency.

In this description, these reference numbers refer to the following features:

5 ground plane

10 first substrate

15 TSVs

20 bondline

30 second substrate

40 third substrate

In one embodiment, the substrates 10, 30 and 40 may be silicon-on-insulator (SOI) substrates with a thin device layer, a buried oxide layer, and a thicker handle layer. The vias 15 may be formed through the thickness of the device layer, extending to the buried oxide. The handle layer may now be removed to complete the backside processing. In another embodiment, a regular, monolithic silicon substrate may be used. In this case, the via may be formed as a blind hole partially through the substrate from the frontside. The backside may subsequently be ground or etched away. In other embodiments, the substrates 10, 30 and 40 may be metal, glass, ceramic or sapphire for example. More generally, the substrates 10, 30 and 40 may be any metal or metal alloy with at least one component of the alloy chosen from column II or III of the periodic table and another component chosen from column V or VI. Exemplary materials include gallium arsenide (GaAs), gallium nitride (GaN), indium arsenide (InAs), and indium phosphide (InP), among many others that can make use of this structure and method.

Numerous other ways for depositing a conductive material into a through hole or blind hole exist in the literature and are known to those skilled in the art for making the through substrate vias 15. Several such methods are described briefly below.

Long, narrow vias 15 are often created by plating a conductive material into a blind hole formed in a substrate. A hole may be created in a substrate by a directional material removal process such as reactive ion etching (RIE). A seed layer may then be deposited conformally over the etched surface, to provide a conductive seed layer to attract the plating material from the plating bath. The hole may then be filled by plating onto the seed layer with a conductive material. Subsequently, the blind end wall of the hole may be removed by etching, sawing or grinding, for example, which may create a via that extends through the thickness of the substrate.

Another known method for making vias 15 is to use an anisotropic etch to form the holes with sloping sidewalls, and to deposit the conductive seed layer material on the sloped walls of the holes. However, this method often results in conductive seed layer material having non-uniform thickness, and the heat conduction in the thin deposited layer is relatively poor. The aspect ratio must also remain near 1:2 (width=2× depth), further limiting the density of the vias. In either case, the deposited layer may be used as a seed layer for the deposition of the conductive filler material by electrochemical plating deposition onto the seed layer. Then, as before, the blind end wall of the hole may be removed to create a via that extends through the substrate.

Other methods for forming electrical vias may be found in U.S. Pat. Nos. 7,233,048 and 8,343,791 (the '048 and '791 patents, respectively) and U.S. patent application Ser. Nos. 13/987,871 and 14/499,287 (the '871 and '287 applications, respectively). Each of these patents and patent applications are incorporated by reference in their entireties.

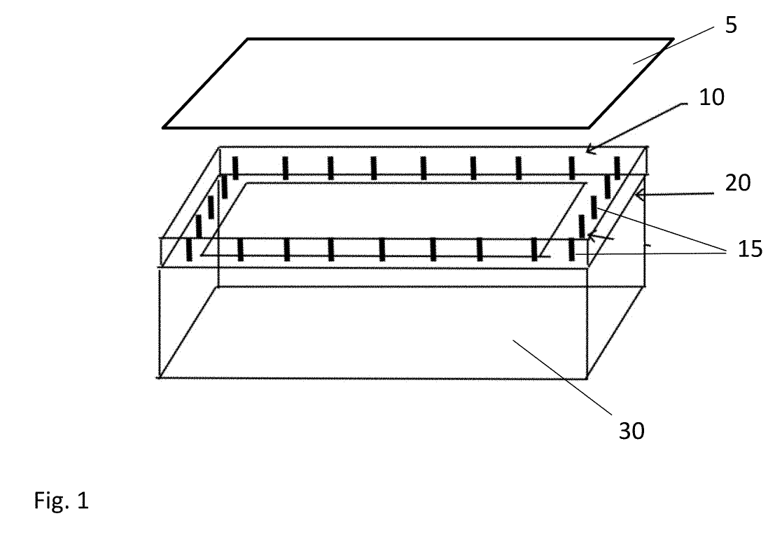

FIG. 1 is a perspective view of an exemplary structure showing the novel bondline. In FIG. 1, a ground plane 5 is disposed adjacent to a first substrate 10 which is bonded to a second substrate 30. The bondline is indicated as reference number 20 between the first substrate 10 and the second substrate 30. A plurality of through substrate vias 15 may be formed in the first substrate 10. These vias 15 may, of course, be filled with a conductive material, and therefore constitute a conductive path between the ground plane 5 and the bondline 20. Accordingly, the through substrate vias 15 effectively ground the bondline 20 at various intervals around the bondline.

As shown in FIG. 1, the through substrate vias 15 maybe located at intervals around the bondline 20. This interval maybe be a fraction of a wavelength of the signal that the device is designed to support.

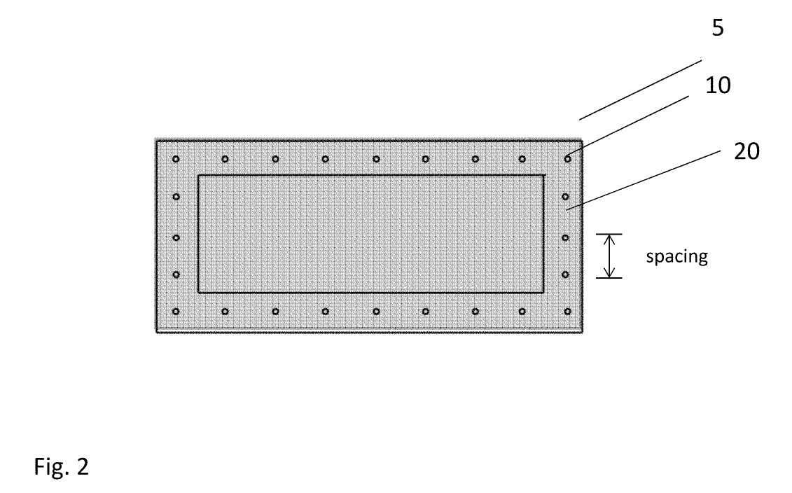

FIG. 2 is a plan view of the novel bondline architecture. In FIG. 2, 5 is the ground plane, 10 is the first substrate, 20 is the bondline, and 15 are the through substrate vias located in the first substrate 10. Not shown because it is below the structures 10, 15 and 20, is the second substrate 30. As shown in FIG. 2, the through substrate vias 15 are placed at intervals around the bondline 20. As previously mentioned, this interval may be a fraction of the wavelength of the RF signal that the structure is designed to support.

As mentioned, the spacing interval between TSVs 15 shown in FIG. 2 may be chosen depending on the frequency the device is designed to handle. For example, using a silicon substrate, and if the characteristic radiation of the signal is expected to be about 80 GHz, then the interval should be at most about (3e14/80 GHz)/(4*c)=93 microns, since the dielectric constant of silicon is about 10. If the bondline is about 500 microns on a side, there should be at least five grounding TSVs one each of the rectangular edges of the bondline.

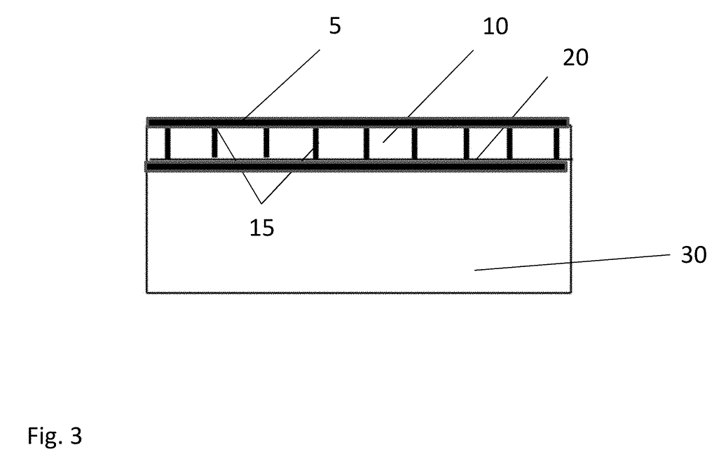

FIG. 3 is a cross-sectional diagram of the novel bondline architecture. As before, in FIG. 3, 5 is the ground plane, 10 is the first substrate, 15 are the through substrate vias in the bondline 20, and 30 is the second substrate. As before, the bondline 20 bonds the first substrate 10 to the second substrate 30. Embedded within the first substrate 10 are a plurality of through substrate vias 15. These vias may be disposed at intervals around the bondline 20, and within the first substrate 10. Together, these through substrate vias 15 form an electrical connection between the ground plane 5 and the bondline 20. Accordingly, the bondline 20 is periodically grounded to the ground plane 5 by the plurality of through substrate vias 15. The bondline 20 therefore cannot readily support radiation which has a wavelength which is a integer multiple of the intervals between the through substrate vias 15.

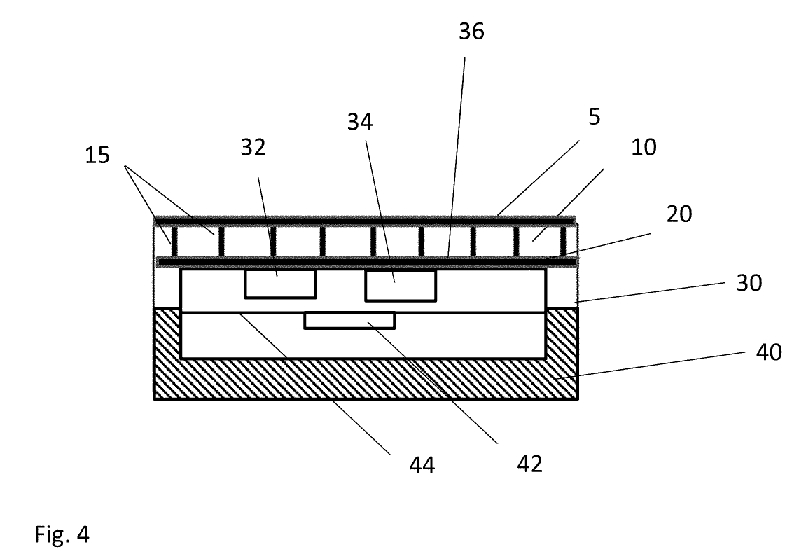

FIG. 4 is a cross-sectional illustration of an embodiment of the novel bondline, as applied to a particular switch structure. The switch structure 1 may be, for example, a dual substrate MEMS switch. The switch is described in some detail in U.S. Pat. No. 7,528,691, issued May 5, 2009 and incorporated by reference in its entirety. In this application, a switch may be formed between an incoming electrode 32 and an outgoing electrode 34. The electrodes may be spanned by a movable gate 42 to close the switch.

The incoming 32 and outgoing 34 electrodes may be fabricated on one substrate, for example on the second substrate 30. The electrostatically movable gate 42 may be formed on another substrate, for example, substrate 40. When a voltage is applied between the movable gate on substrate 40 and the ingoing and outgoing contacts on substrate 30, the cantilever is drawn toward the contacts, thereby closing the switch. Accordingly when the second substrate 30 is bonded to the third substrate 40, the switch is formed.

However in this, as in other applications, it is important to ground the bondline in order to keep the bondline from interfering with the signal passing from the incoming 32 to the outgoing 34 electrodes. The architecture shown in FIG. 4 and described above may effectively suppress signals at the operating frequency of the switch, thereby improving noise, loss and overall performance of the switch.

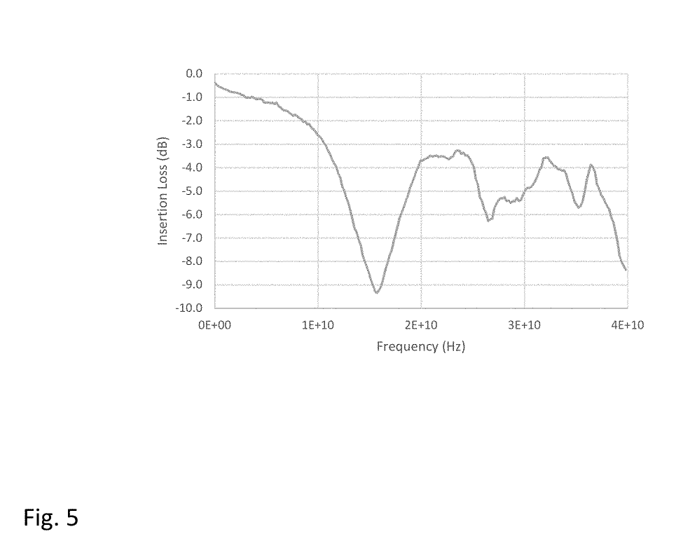

The prior approach of simply forming a bondline between two substrates will create a bond seal that is electrically floating. In this case, the bondline will likely form a standing wave if the total bond length is approximately an integer multiple of the wavelength of the radiation. For current dual substrate relays the bondline is typically 860 um on a square edge, or 3.4 mm total. The phase velocity of traces on Si substrates is generally ˜c/2, although it is difficult to estimate accurately. Thus a drop out is expected at a radiation wavelength of 3.4*4=13.8 mm (=22 GHz). A resonance (drop out) can be seen in FIG. 5 at ˜26 Ghz, in good agreement with this simple model.

Accordingly, FIG. 5 is a data plot showing the suppression of a frequency range within the device using the prior art bondline. As shown in FIG. 5 the frequency range on or around 16 GHz is effectively suppressed without the novel architecture described here. The resonance (drop out) can be seen in FIG. 5 at ˜26 Ghz, in good agreement with this simple model.

Accordingly, to improve this performance, through substrate vias 15 may be placed at intervals around the bondline 20. The TSVs may provide a conductive path between the bondline 20 and a ground plane 5. Accordingly, if the characteristic frequency of a signal is f, its wavelength inside a material is lambda=cεf, where c is the speed of light (about 3e14 microns/sec), ε is the dielectric constant of the material. For example, if the device is intended to switch a signal at frequency f, the TSVs would be placed no further than (3e14/(f*10*4) microns apart. For a 50 GHz signal, the TSVs would be placed every (300000/(50*40)=150 microns or at least one TSV per side of rectangular bondline.

The bondline architecture described above with the bondline grounded at intervals, wherein the interval is a fraction of a wavelength of the signal that the device is designed to support.

The device may be fabricated as described generally in the incorporated '691 patents, and described briefly here. The movable contact or gate 42 may be fabricated by first forming the conductive contact or gate 42 on a plate substrate 40. Plate substrate 40 may be analogous to plate substrate 1000 in the '691 patent. The movable member 44 on which the contact 42 is formed may then be formed by deep reactive ion etching (DRIE) of its shape or perimeter from the device layer of the SOI plate substrate 40. The movable structure 44 may then be released by etching the oxide layer from beneath the etched outline of the movable plate 44.

The vias 32 and 34 may be formed by etching a pair of blind holes into a second via substrate 30. Contacts 32 and 34 may be analogous to contacts 2110 and 2120 in '691 patent. The holes may be covered conformally with a seed layer, and then a conductive material may be plated into the holes 32 and 34. Another metallic region 36 may be formed in addition but electrically isolated from vias 32, 34. This metallization layer 36 may form the opposing electrode on a parallel plate capacitor. The via substrate 30 may then be mated with the plate substrate 40, and the backside of the via substrate 30 may be ground down to expose the through substrate vias 32 and 34. The via substrate 30 may then be bonded to the ground plane substrate 10.

Alternatively, the via substrate may be fabricated first, bonded to the ground plane substrate 10, and this wafer assembly may then be bonded to the plate substrate 40 to form the MEMS switch with ground plane. As mentioned, alternative methods exist for forming the through substrate vias, as detailed, for example, in the incorporated '048 and '791 patents, and the '871 and '287 applications.

To operate the switch, an RF signal may be applied to the contact electrodes 32 and 34. An activating voltage may then be applied to the movable gate 42 and opposing electrode 36. This activating voltage may be applied through another through substrate via that is electrically connected to the movable plate and an opposite polarity voltage may be applied to the electrostatic plate 36 on the via substrate 30. This voltage may cause the movable plate 44 to be drawn towards the opposing electrode, until the gate 42 rests against and spans the contacts 32 and 34. At this point, the switch is closed and the RF signal is communicated from one of contacts 32, 34 to the other of the contacts 32, 34.

Accordingly, a microfabricated structure is disclosed, which supports signals having a characteristic wavelength of λ, comprising a metallic wafer bonding material that bonds a first wafer to a second wafer, a ground plane which is held at ground potential relative to the wafer bonding material, and a plurality of through wafer vias extending through at least one of the first substrate and the second substrate, that defines a conductive path between the ground plane and the metallic bonding material, wherein the through wafer vias are disposed at intervals of between about 2λ and λ/10. The ground plane may be a layer of at least one of copper, gold, silver and platinum about 5 microns thick. The metallic wafer bonding material is at least one of gold, a noble metal, and a metal alloy. The metallic wafer bonding material may be a gold/indium alloy.

In the microfabricated structure disclosed here, the interval between TSVs may be about λ/4 At least one of the first and the second substrate may be a silicon-on-insulator substrate. At least one of the first and the second substrate may be at least one of a silicon, metal, glass and ceramic substrate, a metal and a metal alloy with at least one component of the alloy chosen from column II or III of the periodic table, and another component chosen from column V and VI of the periodic table. The plurality of through wafer vias may comprise a plurality of at least one of copper, nickel, gold and silver vias. An incoming and an outgoing contact for routing a signal into and out of a device cavity may be included on the second substrate in the microfabricated structure. The structure may further include a third substrate with a cantilevered gate electrode formed thereon, wherein the gate electrode spans the incoming and outgoing contacts.

A method for forming a microfabricated structure is disclosed, which supports signals having a characteristic wavelength of λ. The method may include forming a plurality of through wafer vias extending through at least one of a first substrate and a second substrate, that define a conductive path between a ground plane and a metallic bonding material, wherein the through wafer vias are disposed at intervals of between about 2λ and λ/10, forming the ground plane which is held at ground potential relative to the wafer bonding material, and applying the metallic wafer bonding material to the first wafer or the second wafer.

In the method, the ground plane may be a layer of at least one of copper, gold, silver and platinum about 5 microns thick. The metallic wafer bonding material may be at least one of gold, a noble metal, and a metal alloy. The metallic wafer bonding material may be a gold/indium alloy. The interval between TSVs may be about λ/4 At least one of the first and the second substrate may be a silicon-on-insulator substrate. More generally, at least one of the first and the second substrate may be at least one of a silicon, metal, glass and ceramic substrate, a metal and a metal alloy with at least one component of the alloy chosen from column II or III of the periodic table, and another component chosen from column V and VI of the periodic table. The plurality of through wafer vias may comprise a plurality of at least one of copper, nickel, gold and silver vias. The method may further include forming an incoming and an outgoing contact for routing a signal into and out of a device cavity on the second substrate. The method may further comprise forming a cantilevered gate electrode on a third substrate, wherein the gate electrode spans the incoming and outgoing contacts.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Accordingly, the exemplary implementations set forth above, are intended to be illustrative, not limiting.

What is claimed is:

1. A microfabricated structure which supports signals having a characteristic wavelength less than or equal to λ, wherein, comprising:
a metallic wafer bonding material that bonds a first wafer to a second wafer;
a ground plane which is held at ground potential relative to the wafer bonding material; and
a plurality of through wafer vias extending through at least one of the first substrate and the second substrate, that defines a conductive path between the ground plane and the metallic bonding material, wherein the through wafer vias are disposed at intervals of between about 2λ and λ/10.

2. The microfabricated structure of claim 1, wherein the ground plane is a layer of at least one of copper, gold, silver and platinum about 5 microns thick.

3. The microfabricated structure of claim 1, wherein the metallic wafer bonding material is at least one of gold, a noble metal, and a metal alloy.

4. The microfabricated structure of claim 3, wherein the metallic wafer bonding material is a gold/indium alloy.

5. The microfabricated structure of claim 1, wherein the interval is about λ/4

6. The microfabricated structure of claim 1, wherein at least one of the first and the second substrate is a silicon-on-insulator substrate.

7. The microfabricated structure of claim 1, wherein at least one of the first and the second substrate is at least one of a silicon, metal, glass and ceramic substrate, a metal and a metal alloy with at least one component of the alloy chosen from column II or III of the periodic table, and another component chosen from column V and VI of the periodic table.

8. The microfabricated structure of claim 1, wherein the plurality of through wafer vias comprises a plurality of at least one of copper, nickel, gold and silver vias.

9. The microfabricated structure of claim 1, further comprising an incoming and an outgoing contact for routing a signal into and out of a device cavity.

10. The microfabricated structure of claim 9, further comprising a third substrate with a cantilevered gate electrode formed thereon, wherein the gate electrode spans the incoming and outgoing contacts.

11. A method for forming a microfabricated structure which supports signals having a characteristic wavelength of λ, comprising:
forming a plurality of through wafer vias extending through at least one of a first substrate and a second substrate, that define a conductive path between a ground plane and a metallic bonding material, wherein the through wafer vias are disposed at intervals of between about 2λ and λ/10.
forming the ground plane which is held at ground potential relative to the wafer bonding material; and
applying the metallic wafer bonding material to the first wafer or the second wafer.

12. The method of claim 11, wherein the ground plane is a layer of at least one of copper, gold, silver and platinum about 5 microns thick.

13. The method of claim 11, wherein the metallic wafer bonding material is at least one of gold, a noble metal, and a metal alloy.

14. The method of claim 13, wherein the metallic wafer bonding material is a gold/indium alloy.

15. The method of claim 11, wherein the interval is about λ/4

16. The method of claim 11, wherein at least one of the first and the second substrate is a silicon-on-insulator substrate.

17. The method of claim 11, wherein at least one of the first and the second substrate is at least one of a silicon, metal, glass and ceramic substrate, a metal and a metal alloy with at least one component of the alloy chosen from column II or III of the periodic table, and another component chosen from column V and VI of the periodic table.

18. The method of claim 11, wherein the plurality of through wafer vias comprises a plurality of at least one of copper, nickel, gold and silver vias.

19. The method of claim 11, further comprising an incoming and an outgoing contact for routing a signal into and out of a device cavity.

20. The method of claim 19, further comprising a third substrate with a cantilevered gate electrode formed thereon, wherein the gate electrode spans the incoming and outgoing contacts.
